(19) United States
(12) Patent Application Publication
(10) Pub. No.: US 2026/0267397 A1
(43) Pub. Date: Sep. 10, 2026

(54) POWER SAVING TECHNIQUE FOR SINGLE DIE MULTIPLE PACKAGE SCENARIOS

(71) Applicant: QUALCOMM Incorporated, San Diego, CA (US)

(72) Inventors: Surya Chaitanya CHATRATI, Hyderabad (IN); Shruti HANUMANTHAIAH, Bangalore (IN); Anandu MANOHARAN, Idukki (IN); Chiew-Guan TAN, San Diego, CA (US)

(21) Appl. No.: 19/070,112

(22) Filed: Mar. 4, 2025

(51) Int. Cl. G06F 1/3293; G06F 1/3234; G06F 9/50; H10W 44/20; H10W 70/63; H10W 90/00

(52) U.S. Cl. CPC G06F 1/3293; G06F 1/3243; G06F 9/5094; H10W 44/20; H10W 70/635; H10W 90/00; H10W 90/701

(57) ABSTRACT

A method for power saving in single die multiple package scenarios is describe. The method includes identifying used pads and unused pads of a system-on-chip (SoC) according to a pre-programmed value. The method also includes feeding a primary low power mode signal to the unused pads of the SoC during a low power mode of the SoC according to a first package type identified from the pre-programmed value. The method further includes feeding a secondary low power mode signal to the unused pads of the SoC during the low power mode and an active mode of the SoC according to a second package type identified from the pre-programmed value.

### BACKGROUND

Aspects of the present disclosure relate to packaging of integrated circuits and, more particularly, to a system and method for saving power in single die multiple package scenarios.

### Field

Electrical connections exist at each level of a system hierarchy. This system hierarchy includes interconnection of active devices at a lowest system level all the way up to a highest system level of interconnections. Theses interconnect layers can connect different devices together on an integrated circuit. As integrated circuits become more complex, more interconnect layers are used to provide the electrical connections between the devices. More recently, the number of input/output (IO) pad connections has increased due to the substantial number of devices that are now interconnected in state-of-the-art integrated circuit (IC) packages, which involve more intricate processes.

State-of-the-art IC package designs demand a small form factor, low cost, a tight power budget, and high electrical performance. For example, a system-on-chip (SoC) may include multiple processor cores/processor clusters for executing real-world applications. Package design has evolved to meet these divergent goals for enabling SoCs that support multimedia enhancements. These real-world applications drive the complexity of SoCs due to an ever-increasing demand for additional numbers of processor cores/processor clusters, further increasing the number of IO pad connections.

In practice, the same SoC chip is delivered to various customers utilizing different IC package configurations. Depending on the IC package configuration, some of the IO pads are not actively connected as IC inputs or outputs and remain as unused pads. Unfortunately, pad groups that include a combination of used and unused pads are powered on, which contributes to unnecessary power consumption by the unused pads. There is a need to reduce leakage for unused pads as well as to reduce overall power consumption.

### SUMMARY

A method for power saving in single die multiple package scenarios is describe. The method includes identifying used pads and unused pads of a system-on-chip (SoC) according to a pre-programmed value. The method also includes feeding a primary low power mode signal to the unused pads of the SoC during a low power mode of the SoC according to a first package type identified from the pre-programmed value. The method further includes feeding a secondary low power mode signal to the unused pads of the SoC during the low power mode and an active mode of the SoC according to a second package type identified from the pre-programmed value.

An integrated circuit (IC) package is described. The IC package includes a system-on-chip (SoC) die. The IC package also includes input/output (IO) pads, identified as used pads and unused pads of the SoC die according to a pre-programmed value. The IC package further includes control logic coupled to the unused pads of the SoC die and a primary low power mode signal. The control logic to feed the primary low power mode signal to the unused pads of the SoC die according to a first package type identified from the pre-programmed value and to feed a secondary low power mode signal to the unused pads of the SoC die according to a second package type identified from the pre-programmed value.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), configured for single die multiple package power saving scenarios, in accordance with aspects of the present disclosure.

FIG. 2 shows a cross-sectional view illustrating a stacked integrated circuit (IC) package of the system-on-chip (SoC) of FIG. 1.

FIG. 3 shows a cross-sectional view illustrating the stacked integrated circuit (IC) package of FIG. 2, incorporated into a wireless device, according to one aspect of the present disclosure.

FIG. 4 is a schematic diagram conceptually illustrating a calibration circuit to configure single die multiple package power saving scenarios, according to various aspects of the present disclosure.

FIG. 5 is a schematic diagram illustrating a calibration circuit for the control logic of FIG. 4 to configure a system-on-chip (SoC) die according to multiple package power saving scenarios, according to various aspects of the present disclosure.

FIG. 6 is a process flow diagram illustrating a method to configure single die multiple package power saving scenarios, according to various aspects of the present disclosure.

FIG. 7 is a block diagram showing an exemplary wireless communications system in which an aspect of the disclosure may be advantageously employed.

FIG. 8 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced.

A system hierarchy includes interconnection of active devices at a lowest system level all the way up to system level interconnections at a highest level. In particular, electrical connections exist at each of the levels of the system hierarchy to connect different devices together on an integrated circuit. As integrated circuits become more complex, however, more interconnect layers are used to provide the electrical connections between the devices. More recently, the number of interconnect levels for circuitry has substantially increased due to the large number of devices that are now interconnected in state-of-the-art integrated circuit (IC) packages, which involve more intricate processes.

State-of-the-art design of IC packages involves a small form factor, low cost, a tight power budget, and high electrical performance. Package design has evolved to meet these divergent goals for enabling mobile applications that support various technology innovations, which are driving the demand for massive processing speed of an application processor utilized in a system-on-chip (SoC). These technology innovations include, for example, autonomous driving, industry Internet-of-things (IOT), remote medical operations/resource sharing, and infotainment/gaming/education. Other technology innovations include interactive collaborations with artificial intelligence (AI) and virtual reality (VR)/augmented reality (AR)/mixed reality (MR)/extended reality (XR) devices. These real-world applications drive the complexity of SoCs due to an ever-increasing demand for additional numbers of processor cores/processor clusters, further increasing the number of IO pad connections.

In practice, the same SoC chip is delivered to various customers utilizing different IC package configurations. Depending on the IC package configuration, some of the IO pads are not used, but remain as unused pads. Unfortunately, pad groups that include a combination of used and unused pads are powered on, which contributes to unnecessary power consumption by the unused pads. There is a need to reduce leakage for unused pads as well as to reduce overall power consumption.

Various aspects of the present disclosure provide calibration circuitry and a process to configure single die multiple package power saving scenarios. The process to configure single die multiple package power saving scenarios varies according to a package type. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an integrated circuit (IC) device. The terms “substrate,” “wafer,” and “laminate” may be used interchangeably.

According to aspects of the present disclosure, calibration circuitry and a process to configure single die multiple package power saving scenarios are described. For example, a process to configure single die multiple package power saving scenarios first identifies used pads and unused pads of a system-on-chip (SoC) according to a pre-programmed value. When unused pads are detected, a low power signal is asserted to the unused pads of the SoC during both active states and low power states of the SoC. Additionally, the low power signal is asserted to the used pads of the SoC during the low power states of the SoC.

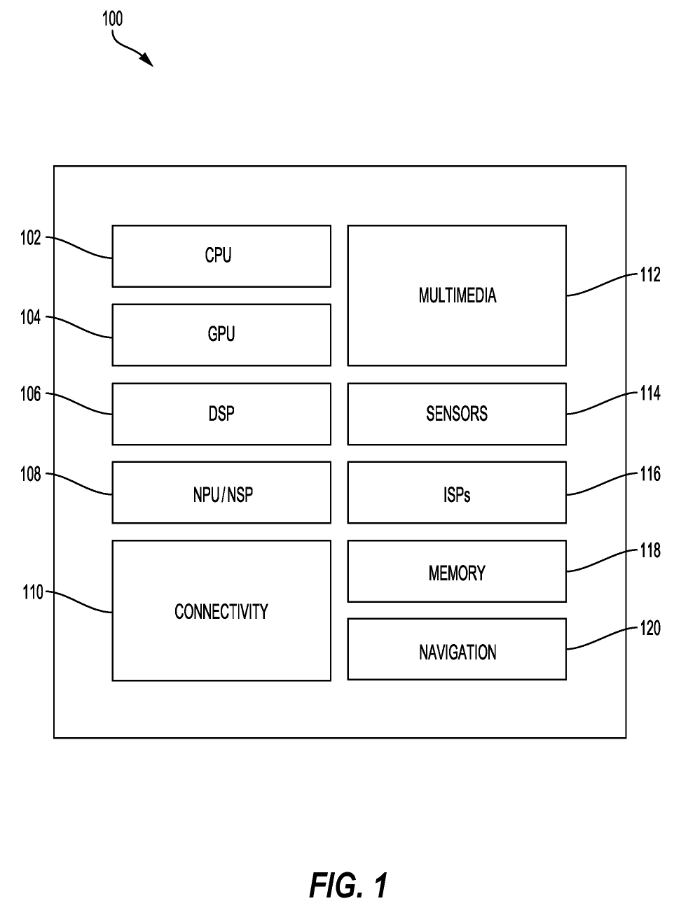

FIG. 1 illustrates an example implementation of a host system-on-chip (SoC) 100, configured for single die multiple package power saving scenarios, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU)/neural signal processor (NSP) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU/NSP 108, and the multimedia engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU/NSP 108 may be based on an ARM instruction set.

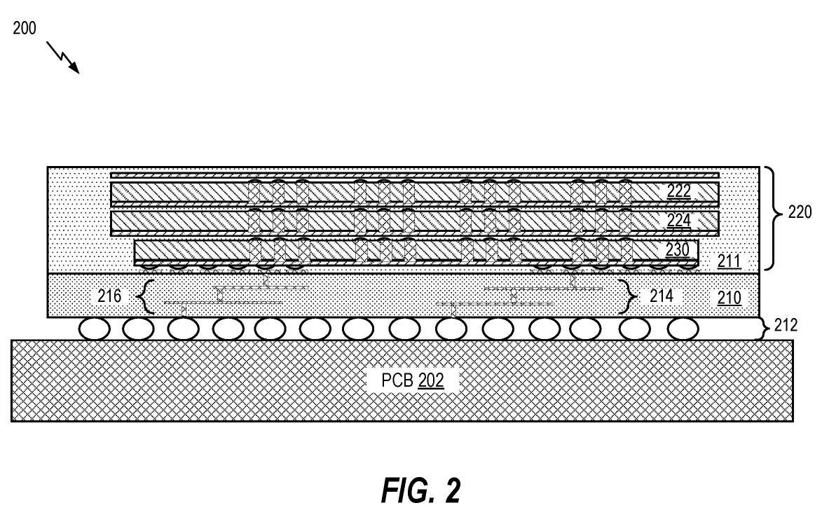

FIG. 2 shows a cross-sectional view illustrating a stacked integrated circuit (IC) package 200 of the system-on-chip (SoC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211 according to a molded embedded package (MEP) configuration (e.g., a first package type). Alternatively, a reduced sized redistribution layer (RDL) package type (e.g., a second package type), other like package type are complemented. In one aspect of the present disclosure, the die 230 is the SoC 100 of FIG. 1.

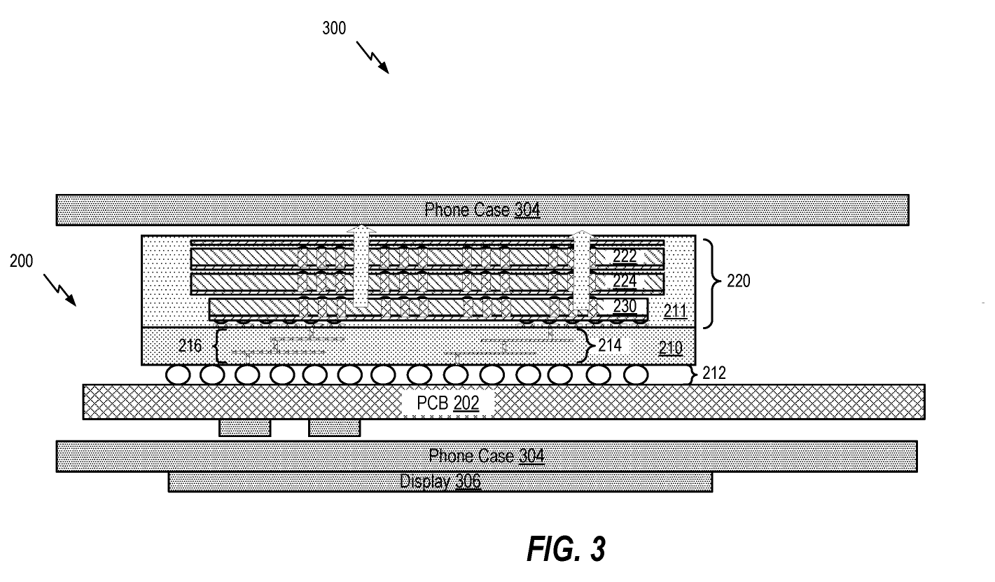

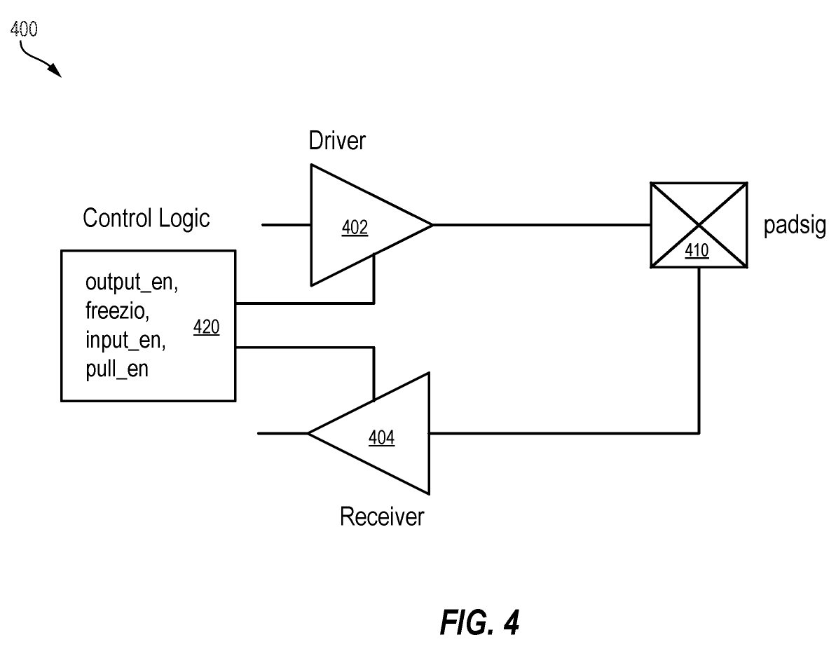

FIG. 3 shows a cross-sectional view illustrating the stacked IC package 200 of FIG. 2, incorporated into a wireless device 300, according to one aspect of the present disclosure. As described, the wireless device 300 may include, but is not limited to, a smartphone, tablet, handheld device, or other limited form factor device configured for 5G communications. Representatively, the stacked IC package 200 is arranged within a phone case 304, including a display 306. In this configuration, a calibration circuitry to configure single die multiple package power saving scenarios is integrated into the stacked IC package 200, for example, as shown in FIG. 4.

FIG. 4 is a schematic diagram conceptually illustrating a calibration circuit 400 to configure single die multiple package power saving scenarios according to various aspects of the present disclosure. The calibration circuit 400 includes a digital driver 402 coupled to an external voltage pad (“PADSIG”) 410 and a digital receiver 404 coupled to the PADSIG 410. The digital driver 402 and the digital receiver 404 operate according to control logic 420.

As shown in FIG. 4, the control logic 420 is configured according to a freezio power control mode and clamps the following signals: (1) an output enable (output_en) signal, (2) a freezio signal, (3) an input enable (input_en), and (4) a pull enable (pull_en) signal. According to a freezio power control mode (“freezio mode”), if an input/output (IO) pad is in a driven mode during the freezio mode, the PADSIG 410 continues driving with a minimum drive strength (e.g., >= 2 milliamps (mA)) during the freezio mode. If the IO pad is in a keeper mode during the freezio mode, the PADSIG 410 remains in the keeper mode and a digital value at the PADSIG 410 is weakly kept and can be overwritten by an external signal.

The power rails used for IO pads in a host system-on-chip (SoC) may include a core logic rail (CX) (e.g., VDD_CX with a voltage of 0.75 volts (V)), and a pad rail (PX) (e.g., VDD_PX having multiple voltage domains: 1.8 V/1.2 V/1.1 V). In chips that support CX collapse or a rock-bottom sleep current (RBSC) power state, the IO pads are put into a low power state by having a freezio port (freezio) of an IO pad driven from an always-on subsystem (AOSS) hardware (HW) block. In operation, the AOSS HW block is active even in a low power state, such as the RBSC power state.

In practice, the CX rail is generally shared across each of the IO pads in a host SoC. By contrast, the PX rail is shared in scenarios where pads are grouped based on an interface protocol/voltage of operation of an external integrated circuit (IC), resulting in multiple pad groups in the host SoC. In SoCs in which the same chip is supplied to multiple customers by having different package configurations, not all of the IOs are used or balled out in smaller packages, which are designed to save cost. In other words, some of the IO pads are unused in certain IC packages, which are referred to as unused pads. Unfortunately, the VDD_PX supply provided by the PX rail is powered on for pad groups that include a combination of used and unused pads, which contributes to unnecessary power consumption.

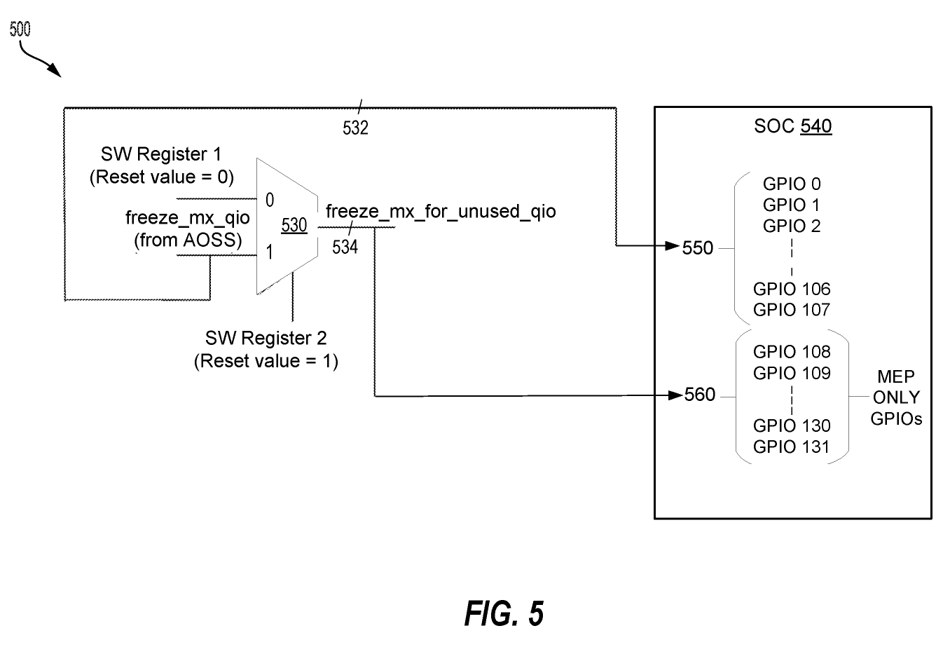

One available option to reduce pad leakage involves a dedicated PX rail for the unused pads, such that the PX rail(s) is powered off from a power management integrated circuit (PMIC). In other words, the PX rail(s) can be collapsed for the unused pads. Unfortunately, this solution involves the addition of one to three (1-3) ball grid array (BGAs) per pad group, which varies based on the corresponding technology node. This BGA addition is further increased if the CX rail is dedicated as well. Moreover, in advanced technology nodes, due to an absence of thick oxide transistors, PX collapse is unsupported by the pads, even if the PX rail(s) is dedicated. In such cases, the leakage with the PX rail(s) active (e.g., PX=OFF and CX=ON) is higher than the leakage with both power rails active (e.g., PX=ON and CX=ON) because turning off the supply associated with unused pads results in a floating node, leading to abnormal circuit behavior. A circuit to configure single die multiple package power saving scenarios for unused pads to reduce power consumption is illustrated, for example, in FIG. 5.

FIG. 5 is a schematic diagram illustrating a calibration circuit 500 for the control logic 420 of FIG. 4 to configure a system-on-chip (SoC) die 540 according to multiple package power saving scenarios, according to various aspects of the present disclosure. For example, the SoC die 540 (e.g., having 132 general purpose input/outputs (GPIOs)) is provided using two different package types: (1) a redistribution layer (RDL) package type (e.g., a smaller package); and (2) a molded embedded package (MEP) type (e.g., a bigger package). In this example, the SoC die 540 includes used GPIOs 550 (e.g., GPIO 0, …, GPIO 107) and unused GPIOs 560 (e.g., GPIO 108, …, GPIO 131) for the RDL package type. As noted, the unused GPIOs 560 are actually utilized in the MEP type configuration.

As shown in FIG. 5, the calibration circuit 500 includes a control logic gate 530 (e.g., a multiplexer) to feed a secondary freezio signal 534 (e.g., a secondary low power mode signal) from a primary freezio signal 532 (e.g., a primary low power mode signal). During operation, system software (SW) may program a first software register (SW register 1) and a second software register (SW register 2) to select between the secondary freezio signal 534 and the primary freezio signal 532. As noted, the primary freezio signal 532 supplied to the used GPIOs 550 (e.g., the used pads) is hardware (HW) driven from an always on subsystem (AOSS) HW block.

In this example, a freezio value of ‘0’ corresponds to an active pad mode, while a freezio value of ‘1’ corresponds to a low power pad mode. Additionally, the first software register (SW register 1) with a reset value of ‘0’ corresponds to a first input 0 and the primary freezio signal 532 corresponds to a second input 1 of the control logic gate 530. Although illustrated with reference to a single, control logic gate 530, it should be recognized that additional control logic gates may handle additional groups of used/unused pads.

According to various aspects of the present disclosure, when unused pads (e.g., unused GPIOs 560) are detected, a secondary low power signal (e.g., the secondary freezio signal 534) is asserted to the unused pads (e.g., unused GPIOs 560) of the SoC die 540 during both active states and low power states of the SoC die 540. Additionally, a primary low power signal (e.g., the primary freezio signal 532) is asserted to the used pads (e.g., used GPIOs 550) of the SoC die 540 during the low power states of the SoC die 540. As noted, the unused GPIOs 560 are actually utilized in the MEP type configuration. In this configuration, a primary low power signal (e.g., the primary freezio signal 532) is asserted to both the used pads (e.g., used GPIOs 550) and the unused pads (e.g., unused GPIOs 560) of the SoC die 540 during the low power states of the SoC die 540.

According to various aspects of the present disclosure, software control of the selection between the primary freezio signal 532 and the secondary freezio signal 534 is based on a value pre-programmed in the SW register 2, which has a reset value of ‘1’. In this implementation, the primary freezio signal 532 is provided for the used GPIOs 550 (e.g., the used pads), and the secondary freezio signal 534 is provided for the unused GPIOs 560 (e.g., the unused pads). As noted, the secondary freezio signal 534 for unused GPIOs 560 (e.g., the unused pads) is completely controllable through software unlike the case of used GPIOs 550 (e.g., the used pads), which are hardware driven from the AOSS HW block (not shown). This capability significantly reduces leakage for the unused GPIOs 560 (e.g., the unused pads) by forcing the unused GPIOs 560 (e.g., the unused pads) into a lowest power mode irrespective of a power state of the SoC die 540 by using the control logic gate 530.

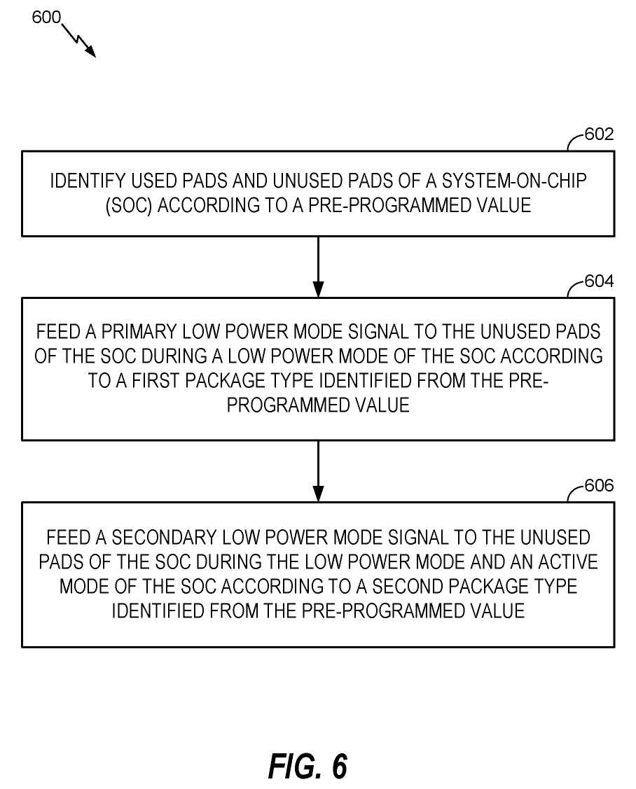

Programming of the SW register 2 to select between the primary freezio signal 532 and the secondary freezio signal 534 is determined based on a pre-programmed fuse value read from a fuse (e.g., by system software of the SoC accessing a fuse of the SoC die 540. For example, the fuse values distinguish between two scenarios: (a) unused pads are used if the fuse is blown (e.g., a first fuse value); or (b) the unused pads are not used if the fuse is not blown (e.g., a second fuse value). According to scenario (a), software programs the SW register 2 for selecting the primary freezio signal 532 to place the unused GPIOs 560 (e.g., the unused pads) in an active mode. Conversely, in scenario (b), software programs the SW register 2 for selecting the secondary freezio signal 534 to place the unused GPIOs 560 (e.g., the unused pads) in a low power mode. A process to configure the control logic gate 530 for enabling single die multiple package power saving scenarios is illustrated, for example, in FIG. 6.

FIG. 6 is a process flow diagram illustrating a method 600 to configure single die multiple package power saving scenarios, according to various aspects of the present disclosure. The method 600 begins at block 602, in which used pads and unused pads of a system-on-chip (SoC) are identified according to a pre-programmed value. For example, as shown in FIG. 5, programming of the SW register 2 to select between the primary freezio signal 532 and the secondary freezio signal 534 is determined based on a pre-programmed fuse value read from a fuse (e.g., by system software of the SoC accessing a fuse of the SoC die 540. For example, the fuse values distinguish between two scenarios: (a) unused pads are used if the fuse is blown (e.g., a first fuse value); or (b) the unused pads are not used if the fuse is not blown (e.g., a second fuse value).

At block 604, a primary low power mode signal is feed to the unused pads of the SoC during a low power mode of the SoC according to a first package type identified from the pre-programmed value. At block 606, a secondary low power mode signal is feed to the unused pads of the SoC during the low power mode and an active mode of the SoC according to a second package type identified from the pre-programmed value. For example, as shown in FIG. 5, when unused pads (e.g., unused GPIOs 560) are detected, a secondary low power signal (e.g., the secondary freezio signal 534) is asserted to the unused pads (e.g., unused GPIOs 560) of the SoC die 540 during both active states and low power states of the SoC die 540. Additionally, a primary low power signal (e.g., the primary freezio signal 532) is asserted to the used pads (e.g., used GPIOs 550) of the SoC die 540 during the low power states of the SoC die 540.

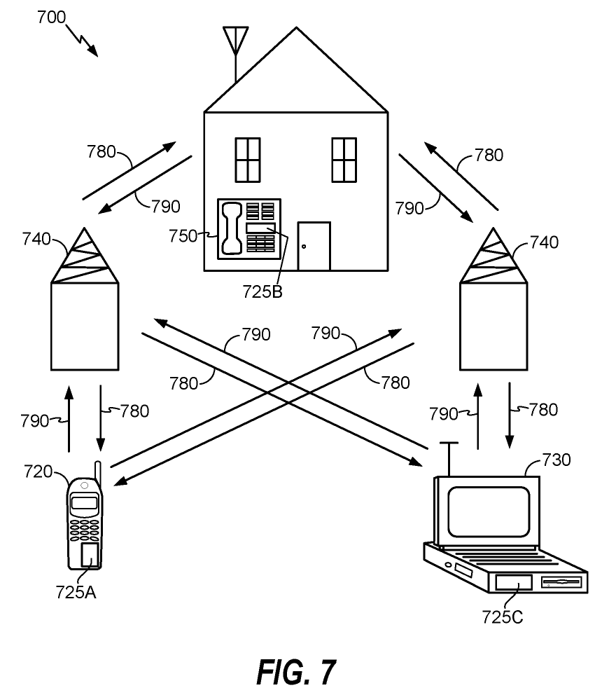

FIG. 7 is a block diagram showing an exemplary wireless communications system 700 in which an aspect of the present disclosure may be advantageously employed. For purposes of illustration, FIG. 7 shows three remote units 720, 730, and 750, and two base stations 740. It will be recognized that wireless communications systems may have many more remote units and base stations. Remote units 720, 730, and 750 include IC devices 725A, 725B, and 725C that include the disclosed single die multiple package power saving scenarios. It will be recognized that other devices may also include the disclosed single die multiple package power saving scenarios, such as the base stations, switching devices, and network equipment. FIG. 7 shows forward link signals 780 from the base stations 740 to the remote units 720, 730, and 750, and reverse link signals 790 from the remote units 720, 730, and 750 to the base stations 740.

In FIG. 7, remote unit 720 is shown as a mobile telephone, remote unit 730 is shown as a portable computer, and remote unit 750 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 7 illustrates remote units according to the aspects of the present disclosure, the disclosure is not limited to these exemplary illustrated units. Aspects of the present disclosure may be suitably employed in many devices, which include the disclosed single die multiple package power saving scenarios.

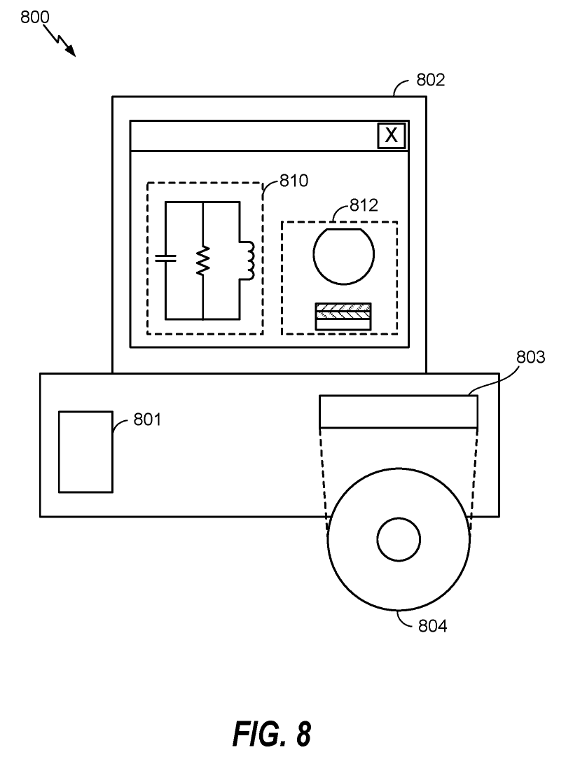

FIG. 8 is a block diagram illustrating a design workstation used for circuit, layout, and logic design of a semiconductor component, such as the capacitors disclosed above. A design workstation 800 includes a hard disk 801 containing operating system software, support files, and design software such as Cadence or OrCAD. The design workstation 800 also includes a display 802 to facilitate design of a circuit 810 or an integrated circuit (IC) component 812, supporting single die multiple package power saving scenarios. A storage medium 804 is provided for tangibly storing the design of the circuit 810 or the IC component (e.g., the single die multiple package power saving scenarios). The design of the circuit 810 or the IC component 812 may be stored on the storage medium 804 in a file format such as GDSII or GERBER. The storage medium 804 may be a CD-ROM, DVD, hard disk, flash memory, or other appropriate device. Furthermore, the design workstation 800 includes a drive apparatus 803 for accepting input from or writing output to the storage medium 804.

Data recorded on the storage medium 804 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 804 facilitates the design of the circuit 810 or the IC component 812 by decreasing the number of processes for designing semiconductor wafers.

### Example Aspects

1. A method for power saving in single die multiple package scenarios, the method comprising:

identifying used pads and unused pads of a system-on-chip (SoC) according to a pre-programmed value;

feeding a primary low power mode signal to the unused pads of the SoC during a low power mode of the SoC according to a first package type identified from the pre-programmed value; and

feeding a secondary low power mode signal to the unused pads of the SoC during the low power mode and an active mode of the SoC according to a second package type identified from the pre-programmed value.

2. The method of clause 1, in which identifying further comprises:

accessing, by system software, a fuse of the SoC;

identifying each pad of the SoC as a used pad associated with the first package type according to a first fuse value; and

identifying the unused pads associated with the second package type according to a second fuse value.

3. The method of clause 2, in which the unused pads associated with the second package type according to the second fuse value are in a low power pad mode during both the active mode and the low power mode of the SoC.

4. The method of clause 2, in which the unused pads associated with the first package type according to the first fuse value are in a low power mode during the low power mode of the SoC and in the active mode during the active mode of the SoC.

5. The method of clause 2, in which the first package type according to the first fuse value comprises a molded embedded package (MEP) type, and the second package type according to the second fuse value comprises a redistribution layer (RDL) package type.

6. The method of clause 2, further comprising programming control logic to drive the primary low power mode signal to both the used pads and the unused pads of the SoC during the low power mode of the SoC in the first package type.

7. The method of any of clauses 1-6, further comprising programming control logic to drive the secondary low power mode signal to the unused pads of the SoC during the active mode of the SoC.

8. The method of any of clauses 1-7, further comprising asserting the secondary low power mode signal to place the unused pads in a low power mode during both the low power mode and the active mode of the SoC.

9. The method of any of clauses 1-8, in which the used pads and the unused pads of the SoC comprise general purpose input/outputs (GPIOs).

10. An integrated circuit (IC) package, comprising:

a system-on-chip (SoC) die;

a plurality of input/output (IO) pads, identified as used pads and unused pads of the SoC die according to a pre-programmed value; and

control logic coupled to the unused pads of the SoC die and a primary low power mode signal, the control logic feeding the primary low power mode signal to the unused pads of the SoC die according to a first package type identified from the pre-programmed value and feeding a secondary low power mode signal to the unused pads of the SoC die according to a second package type identified from the pre-programmed value.

11. The IC package of clause 10, in which the control logic comprises a multiplexer.

12. The IC package of any of clauses 10 or 11, in which the control logic is further to access a fuse of the SoC die, to identify each pad of the SoC die as a used pad associated with the first package type according to a first fuse value, and to identify the unused pads associated with the second package type according to a second fuse value.

13. The IC package of clause 12, in which the unused pads associated with the second package type according to the second fuse value are in a low power pad mode during both an active mode and a low power mode of the SoC die.

14. The IC package of clause 12, in which the unused pads associated with the first package type according to the first fuse value are in a low power mode during the low power mode of the SoC die and in an active mode during the active mode of the SoC die.

15. The IC package of clause 12, in which the first package type according to the first fuse value comprises a molded embedded package (MEP) type, and the second package type according to the second fuse value comprises a redistribution layer (RDL) package type.

16. The IC package of clause 12, in which the control logic is further to drive the primary low power mode signal to both the used pads and the unused pads of the SoC die during the low power mode of the SoC die in the first package type.

17. The IC package of any of clauses 10-16, in which the control logic is further to drive the secondary low power mode signal to the unused pads of the SoC die during an active mode of the SoC die.

18. The IC package of any of clauses 10-17, in which the control logic is further to assert the secondary low power mode signal to place the unused pads in a low power mode during both a low power mode and an active mode of the SoC die.

19.The IC package of any of clauses 10-18, in which the used pads and the unused pads of the SoC die comprise general purpose input/outputs (GPIOs).

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray^{®} disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined may be applied to other variations without departing from the spirit or scope of the disclosure. Thus, the disclosure is not intended to be limited to the examples and designs described but is to be accorded the widest scope consistent with the principles and novel features disclosed.

What is claimed is:

1. A method for power saving in single die multiple package scenarios, the method comprising:
identifying used pads and unused pads of a system-on-chip (SoC) according to a pre-programmed value;
feeding a primary low power mode signal to the unused pads of the SoC during a low power mode of the SoC according to a first package type identified from the pre-programmed value; and
feeding a secondary low power mode signal to the unused pads of the SoC during the low power mode and an active mode of the SoC according to a second package type identified from the pre-programmed value.

2. The method of claim 1, in which identifying further comprises:
accessing, by system software, a fuse of the SoC;
identifying each pad of the SoC as a used pad associated with the first package type according to a first fuse value; and
identifying the unused pads associated with the second package type according to a second fuse value.

3. The method of claim 2, in which the unused pads associated with the second package type according to the second fuse value are in a low power pad mode during both the active mode and the low power mode of the SoC.

4. The method of claim 2, in which the unused pads associated with the first package type according to the first fuse value are in a low power mode during the low power mode of the SoC and in the active mode during the active mode of the SoC.

5. The method of claim 2, in which the first package type according to the first fuse value comprises a molded embedded package (MEP) type, and the second package type according to the second fuse value comprises a redistribution layer (RDL) package type.

6. The method of claim 2, further comprising programming control logic to drive the primary low power mode signal to both the used pads and the unused pads of the SoC during the low power mode of the SoC in the first package type.

7. The method of claim 1, further comprising programming control logic to drive the secondary low power mode signal to the unused pads of the SoC during the active mode of the SoC.

8. The method of claim 1, further comprising asserting the secondary low power mode signal to place the unused pads in a low power mode during both the low power mode and the active mode of the SoC.

9. The method of claim 1, in which the used pads and the unused pads of the SoC comprise general purpose input/outputs (GPIOs).

10. An integrated circuit (IC) package, comprising:
a system-on-chip (SoC) die;
a plurality of input/output (IO) pads, identified as used pads and unused pads of the SoC die according to a pre-programmed value; and
control logic coupled to the unused pads of the SoC die and a primary low power mode signal, the control logic feeding the primary low power mode signal to the unused pads of the SoC die according to a first package type identified from the pre-programmed value and feeding a secondary low power mode signal to the unused pads of the SoC die according to a second package type identified from the pre-programmed value.

11. The IC package of claim 10, in which the control logic comprises a multiplexer.

12. The IC package of claim 10, in which the control logic is further to access a fuse of the SoC die, to identify each pad of the SoC die as a used pad associated with the first package type according to a first fuse value, and to identify the unused pads associated with the second package type according to a second fuse value.

13. The IC package of claim 12, in which the unused pads associated with the second package type according to the second fuse value are in a low power pad mode during both an active mode and a low power mode of the SoC die.

14. The IC package of claim 12, in which the unused pads associated with the first package type according to the first fuse value are in a low power mode during the low power mode of the SoC die and in an active mode during the active mode of the SoC die.

15. The IC package of claim 12, in which the first package type according to the first fuse value comprises a molded embedded package (MEP) type, and the second package type according to the second fuse value comprises a redistribution layer (RDL) package type.

16. The IC package of claim 12, in which the control logic is further to drive the primary low power mode signal to both the used pads and the unused pads of the SoC die during the low power mode of the SoC die in the first package type.

17. The IC package of claim 10, in which the control logic is further to drive the secondary low power mode signal to the unused pads of the SoC die during an active mode of the SoC die.

18. The IC package of claim 10, in which the control logic is further to assert the secondary low power mode signal to place the unused pads in a low power mode during both a low power mode and an active mode of the SoC die.

19. The IC package of claim 10, in which the used pads and the unused pads of the SoC die comprise general purpose input/outputs (GPIOs).
